(19) United States
(12) Patent Application Publication
(10) Pub. No.: US 2024/0333299 A1
(43) Pub. Date: Oct. 3, 2024

(54) SUCCESSIVE APPROXIMATION A/D CONVERTER

(71) Applicant: ROHM Co., LTD., Kyoto (JP)

(72) Inventor: Masato Tachibana, Kyoto (JP)

(21) Appl. No.: 18/615,005

(22) Filed: Mar. 25, 2024

(30) Foreign Application Priority Data
Mar. 29, 2023 (JP) 2023-054390

(51) Int. Cl. H03M 1/46

(52) U.S. Cl. CPC H03M 1/46

(57) ABSTRACT

Provided is a successive approximation analog-to-digital converter including a capacitive digital-to-analog converter that samples an analog signal corresponding to the analog input signal and that generates an analog output signal corresponding to a sampling result and a digital input, a comparator that compares the analog output signal and a comparison standard voltage, and a control circuit that generates the digital input corresponding to a comparison result obtained by the comparator, in which the capacitive digital-to-analog converter includes an input node that receives the analog signal, a plurality of capacitors, and an adjustment capacitor charged with an adjustment voltage, and supplies the analog signal to the plurality of capacitors through the input node to sample the analog signal, and the adjustment capacitor supplies a voltage corresponding to the adjustment voltage to the input node before next sampling is performed after the successive approximation.

### CROSS REFERENCE TO RELATED APPLICATIONS

This application claims priority benefit of Japanese Patent Application No. JP 2023-054390 filed in the Japan Patent Office on Mar. 29, 2023. Each of the above-referenced applications is hereby incorporated herein by reference in its entirety.

### BACKGROUND

The present disclosure relates to a successive approximation analog-to-digital (A/D) converter.

A successive approximation A/D converter (hereinafter, also referred to as a “successive approximation ADC”) is known as a type of an A/D converter that converts an analog input signal into a digital output signal. In a case of the successive approximation ADC including a capacitive digital-to-analog (D/A) converter (hereinafter, also referred to as a “capacitive DAC”), the capacitive DAC samples an analog signal corresponding to an analog input signal, and a comparator performs successive approximation of the sampled signal and a standard signal, thereby generating a digital output signal corresponding to a result of the successive approximation.

An example of the related art is disclosed in Japanese Patent Laid-open No. 2017-192099.

### BRIEF DESCRIPTION OF THE DRAWINGS

FIG. 1 is a schematic block diagram of a successive approximation ADC according to a related technique;

FIG. 2 is a diagram for describing an action of the successive approximation ADC according to the related technique when a phase of successive approximation is switched to a phase of sampling;

FIG. 3 is a circuit diagram illustrating a successive approximation ADC according to an embodiment of the present disclosure;

FIG. 4 is a circuit diagram of a capacitive DAC according to the embodiment of the present disclosure;

FIG. 5 depicts the capacitive DAC during sampling;

FIG. 6 depicts the capacitive DAC at the start of successive approximation;

FIG. 7 depicts the capacitive DAC at the end of the successive approximation;

FIG. 8 depicts the capacitive DAC in adjusting a voltage of an input path;

FIG. 9 depicts the capacitive DAC in connecting one end of each of a plurality of capacitors to the input path;

FIG. 10 is a circuit diagram of a capacitive DAC according to a comparative technique;

FIG. 11 depicts the capacitive DAC in sampling an analog voltage;

FIG. 12 depicts the capacitive DAC at the start of successive approximation; and

FIG. 13 depicts the capacitive DAC at the end of the successive approximation.

### DETAILED DESCRIPTION

### (Overview)

An overview of some exemplary embodiments of the present disclosure will be described. The overview briefly describes some concepts of one or a plurality of embodiments for basic understanding of the embodiments as a preface to detailed explanation described later; the overview does not limit the extent of the technology or the disclosure. The overview is not a comprehensive overview of all conceivable embodiments, and the overview is intended to neither specify important elements of all the embodiments nor define the scope of part or all of the aspects. For convenience, “one embodiment” may be used to represent one embodiment (example or modification) or a plurality of embodiments (examples or modifications) disclosed in the present specification.

A successive approximation A/D converter according to one embodiment generates a digital output signal corresponding to an analog input signal. The successive approximation A/D converter includes a capacitive D/A converter that samples an analog signal corresponding to the analog input signal and that generates an analog output signal corresponding to a sampling result and a digital input, a comparator that compares the analog output signal and a comparison standard voltage, and a control circuit that generates the digital input corresponding to a comparison result obtained by the comparator. The capacitive D/A converter includes an input node that receives the analog signal, a plurality of capacitors, and an adjustment capacitor charged with an adjustment voltage. The capacitive D/A converter supplies the analog signal to the plurality of capacitors through the input node to sample the analog signal. The comparator performs successive approximation of the analog output signal in relation to each bit from a most significant bit to a least significant bit of the digital output signal and the comparison standard voltage. The control circuit generates the digital output signal in reference to a result of the successive approximation by the comparator. The adjustment capacitor supplies a voltage corresponding to the adjustment voltage to the input node before next sampling is performed after the successive approximation.

According to the configuration, the adjustment capacitor can adjust the voltage of the input node before the next sampling is performed in the capacitive DAC after the successive approximation. This can suppress the change in the voltage at the one ends of the plurality of capacitors when the plurality of capacitors are connected to the input node or when the analog signal is input to the input node in the next sampling. As a result, the generation of the kick-back noise during the sampling can be suppressed.

In one embodiment, the capacitive D/A converter may further include an output node connected to another end of each of the plurality of capacitors and configured to output the analog output signal. The adjustment capacitor may supply the voltage corresponding to the adjustment voltage to the input node when one end of the adjustment capacitor is connected to the input node and another end of the adjustment capacitor is connected to the output node supplied with a circuit standard voltage.

In one embodiment, the successive approximation A/D converter may further include a switch arranged between a circuit that outputs the analog signal and the input node. The other end of each of the plurality of capacitors may be connected to the input node when the switch is off and the one end of the adjustment capacitor is connected to the input node.

In one embodiment, the capacitive D/A converter may supply a circuit standard voltage or a reference voltage to one end of each of the plurality of capacitors according to the digital input to thereby generate the analog output signal. The adjustment capacitor may be charged with the adjustment voltage corresponding to the comparison standard voltage and the reference voltage when the reference voltage is supplied to one end of the adjustment capacitor and the comparison standard voltage is supplied to another end of the adjustment capacitor during the sampling of the analog signal.

In one embodiment, the capacitive D/A converter may further include an output node connected to another end of each of the plurality of capacitors and configured to output the analog output signal. The other end of the adjustment capacitor may be charged with the adjustment voltage when the other end of the adjustment capacitor is connected to the output node supplied with the comparison standard voltage during the sampling of the analog signal.

In one embodiment, the capacitive D/A converter may supply a circuit standard voltage or a reference voltage to one end of each of the plurality of capacitors according to the digital input to thereby generate the analog output signal. The adjustment voltage may be a voltage one half of the reference voltage.

In one embodiment, capacitance of the adjustment capacitor may be combined capacitance of the plurality of capacitors.

A preferred embodiment will now be described with reference to the drawings. The same reference signs are provided to the same or equivalent constituent elements, members, and processes illustrated in the drawings, and duplicate description will appropriately be omitted. The embodiment is exemplary and not intended to limit the disclosure or the technology. All features and combinations of the features described in the embodiment may not be essential for the disclosure and the technology.

### Related Technique and its Problem

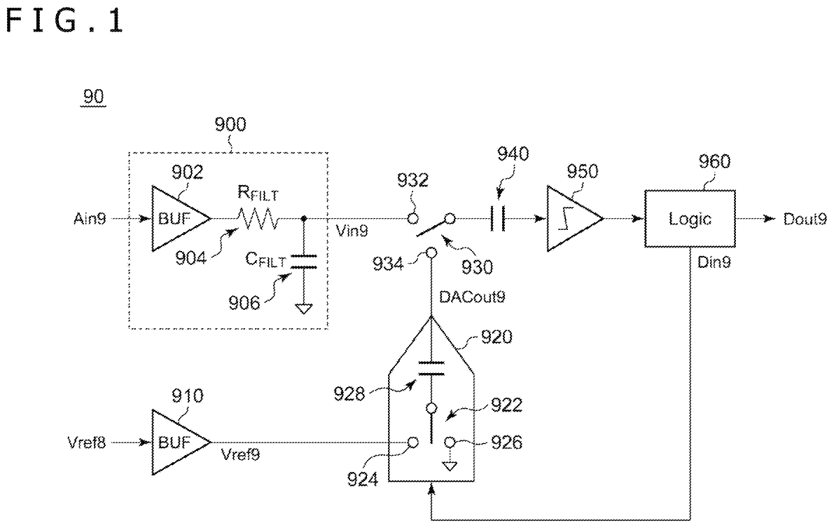

FIG. 1 is a schematic block diagram of a successive approximation ADC 90 according to a related technique. The successive approximation ADC 90 samples an analog voltage Vin9 corresponding to an analog input signal Ain9 and performs successive approximation of an output voltage DACout9 of a capacitive DAC 920 and a comparison standard voltage to generate a digital output signal Dout9. The successive approximation ADC 90 according to the related technique mainly includes an input circuit 900, a buffer circuit 910, the capacitive DAC 920, an input switch 930, a sampling capacitor 940, a comparator 950, and a logic circuit 960.

The input circuit 900 generates the analog voltage Vin9 corresponding to the analog input signal Ain9. The input circuit 900 includes a buffer circuit 902, a resistance element 904, and a capacitor 906. The resistance element 904 and the capacitor 906 form a first-order resistor-capacitor (RC) filter. The resistance value of the resistance element 904 is R_{FILT}, and the capacitance value of the capacitor 906 is C_{FILT}. The analog input signal Ain9 is input to the buffer circuit 902, and the analog voltage Vin9 is generated through the RC filter including the resistance element 904 and the capacitor 906.

The buffer circuit 910 receives a reference voltage Vref8 and outputs a voltage Vref9 corresponding to the reference voltage Vref8 to the capacitive DAC 920.

The capacitive DAC 920 generates the analog output voltage DACout9 corresponding to a digital input Din9. The capacitive DAC 920 includes a switch 922, a reference terminal 924 supplied with the voltage Vref9, a ground terminal 926, and a capacitor 928. The switch 922 connects one end of the capacitor 928 to the reference terminal 924 or the ground terminal 926 according to a digital input Din. The output voltage DACout9 corresponding to the connection point of the switch 922 is generated at another end of the capacitor 928.

The input switch 930 connects one end of the sampling capacitor 940 to an input terminal 932 or a DAC terminal 934. When the connection point of the input switch 930 is the input terminal 932, the sampling capacitor 940 samples the analog voltage Vin9. On the other hand, when the connection point of the input switch 930 is the DAC terminal 934, the comparator 950 performs successive approximation of a voltage corresponding to the output voltage DACout9 of the capacitive DAC 920 and the analog voltage Vin9 and a comparison standard voltage.

The logic circuit 960 generates the digital input Din9 according to a comparison result obtained by the comparator 950. The logic circuit 960 also generates the digital output signal Dout9 according to a result of the successive approximation performed by the comparator 950.

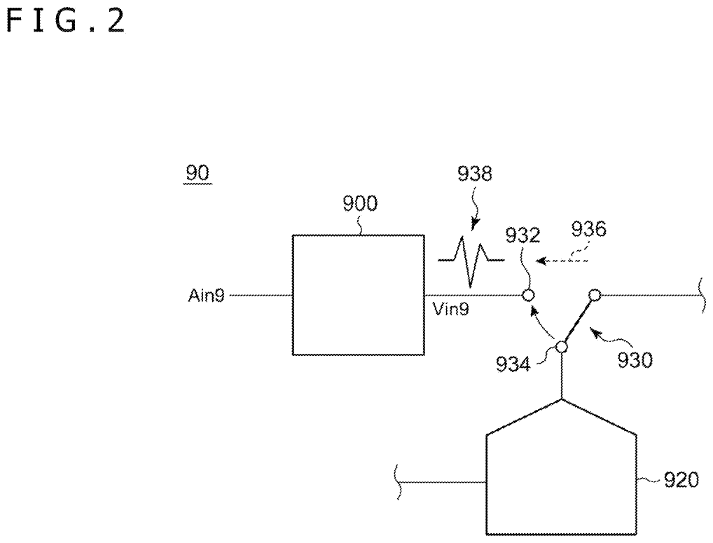

FIG. 2 is a diagram for describing an action of the successive approximation ADC 90 according to the related technique when a phase of successive approximation is switched to a phase of sampling. The connection point of the input switch 930 is switched from the DAC terminal 934 to the input terminal 932 when the phase of successive approximation is switched to the phase of sampling. In this case, there is a flow 936 of charge from the capacitive DAC 920, and the analog voltage Vin9 is fluctuated at the input terminal 923. As a result, kick-back noise 938 is generated. If the oscillation of the analog voltage Vin9 caused by the kick-back noise 938 is not settled within a predetermined period of time, the conversion accuracy of the successive approximation ADC 90 is reduced.

A filter and a buffer circuit are typically inserted into the input side to prevent the reduction in the conversion accuracy of the successive approximation ADC 90 caused by the kick-back noise 938. The first-order RC filter including the resistance element 904 and the capacitor 906 is used as the filter. However, a large-capacity capacitor 906 may be necessary to suppress a sharp oscillation of the analog voltage Vin9 caused by the kick-back noise 938, and this restricts the band of the input signal Ain9. In addition, a sufficient slew rate may be necessary for the buffer circuit 902 itself to suppress the oscillation of the analog voltage Vin9, and this increases the current consumption. Therefore, there is a challenge of reducing the effect of the kick-back noise 938 without restricting the band of the input signal Ain9 and increasing the current consumption.

### Embodiment

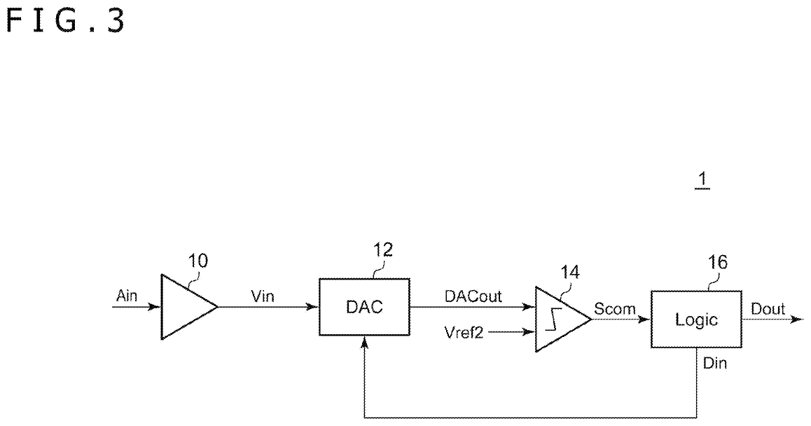

FIG. 3 is a circuit diagram illustrating a successive approximation ADC 1 according to one embodiment of the present disclosure. The successive approximation ADC 1 according to the present embodiment generates a digital output signal Dout corresponding to an analog input signal Ain. The successive approximation ADC 1 includes a buffer circuit 10, a capacitive D/A converter 12, a comparator 14, and a logic circuit 16 (control circuit).

The buffer circuit 10 receives the analog input signal Ain and generates an analog voltage Vin (analog signal) corresponding to the analog input signal Ain. The analog voltage Vin is input to the capacitive DAC 12.

The capacitive DAC 12 samples an analog signal DACin corresponding to the analog input signal Ain and generates an analog output voltage DACout (analog output signal) corresponding to a digital input Din. Specifically, the capacitive DAC 12 sequentially generates an output voltage DACout in relation to each bit from a most significant bit to a least significant bit of the digital output signal Dout according to the digital input Din. The analog output voltage DACout is input to the comparator 14.

The comparator 14 compares the output voltage DACout generated by the capacitive DAC 12 and a comparison standard voltage Vref2 and generates a signal Scom corresponding to a comparison result. Hereinafter, the voltage value of the comparison standard voltage Vref2 will be referred to as Vref2. The comparator 14 also performs successive approximation of the output voltage DACout in relation to each bit from the most significant bit to the least significant bit of the digital output signal Dout and the comparison standard voltage Vref2. The comparator 14 generates a signal Scom corresponding to each result of the successive approximation.

The logic circuit 16 generates the digital input Din corresponding to the comparison result (specifically, the signal Scom) obtained by the comparator 14. The logic circuit 16 generates the digital output signal Dout in reference to the result of the successive approximation by the comparator 14. Specifically, the logic circuit 16 determines 0 or 1 of each bit from the most significant bit to the least significant bit in reference to the comparison result obtained by the comparator 14, to generate the output signal Dout. Although the logic circuit 16 generates the output signal Dout of four bits in the example described in the present embodiment, the number of bits of the output signal Dout may be three or less or may be five or more.

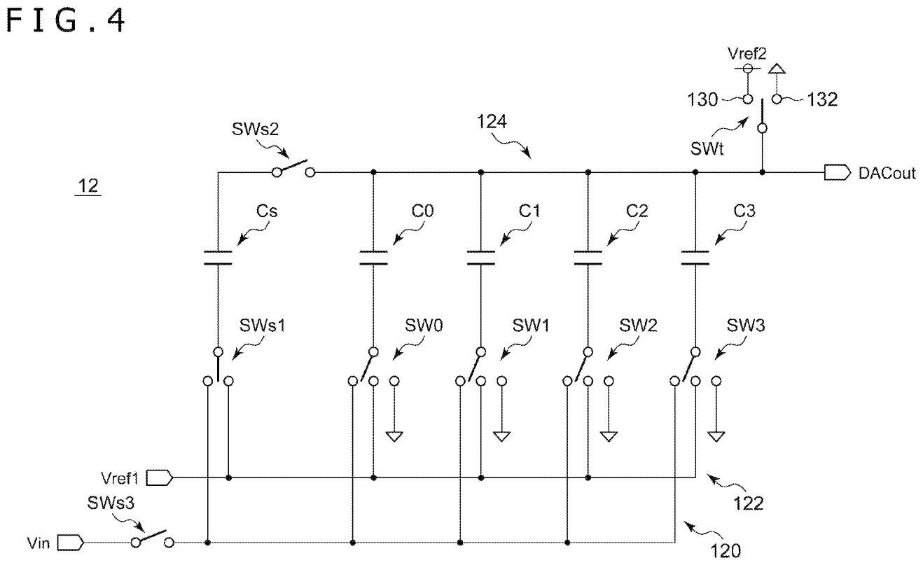

FIG. 4 is a circuit diagram of the capacitive DAC 12 according to the embodiment of the present disclosure. The capacitive DAC 12 according to the present embodiment mainly includes a plurality of capacitors C0 to C3, an adjustment capacitor Cs, switches SW0 to SW3, SWs1 to SWs3, and SWt, an input path 120 (input node), a standard path 122, and an output path 124 (output node).

The input path 120 is a node that receives the analog voltage Vin through the switch SWs3. The switch SWs3 is arranged between the buffer circuit 10 that outputs the analog voltage Vin and the input path 120. The analog voltage Vin is input to the input path 120 when the switch SWs3 is on, and the analog voltage Vin is not input to the input path 120 when the switch SWs3 is off. A reference voltage Vref1 is input to the standard path 122. Hereinafter, the voltage value of the reference voltage Vref1 will be referred to as Vref1.

The plurality of capacitors C0 to C3 correspond to four bits of the digital output signal Dout. Specifically, the capacitor C3 corresponds to the most significant bit. The capacitor C2 corresponds to a second bit. The capacitor C1 corresponds to a third bit. The capacitor C0 corresponds to a least significant bit. The capacitance values of the capacitors C0, C1, C2, and C3 are [1C], [2C], [4C], and [8C], respectively, where “C” represents a standard capacitance value. Hence, the capacitors C0 to C3 have capacitance values weighted by a predetermined ratio (=2^{x}C (where x=integers 0 to 3)). Hereinafter, one end of the capacitor represents an end of the capacitor closer to the input path 120, and another end of the capacitor represents an end of the capacitor closer to the output path 124.

The switches SW0 to SW3 respectively connect the one ends of the plurality of capacitors C0 to C3 to the input path 120, the standard path 122, or a ground terminal. The action of the switches SW0 to SW3 is controlled according to the digital input Din of the logic circuit 16.

The output path 124 is a node that outputs the analog output voltage DACout. The output path 124 is connected to the other ends of the plurality of capacitors C0 to C3. The switch SWt can connect the output path 124 to a comparison standard terminal 130 or a ground terminal 132. The switch SWt can also not connect (turn off) the output path 124 to the comparison standard terminal 130 or the ground terminal 132. The comparison standard voltage Vref2 is supplied to the comparison standard terminal 130. Although the comparison standard voltage Vref2 is not particularly limited to any kind, it is assumed that the comparison standard voltage Vref2 according to the present embodiment is a voltage one half of the reference voltage Vref1 (=½×Vref1). A circuit standard voltage (hereinafter, also referred to as “GND”) is supplied to the ground terminal.

The adjustment capacitor Cs is charged with an adjustment voltage and supplies a voltage corresponding to the adjustment voltage to the input path 120. Specifically, the adjustment capacitor Cs supplies the voltage corresponding to the adjustment voltage to the input path 120 before the capacitive DAC 12 performs the next sampling after the successive approximation in the comparator 14. In the present embodiment, the adjustment capacitor Cs supplies the adjustment voltage to the input path 120 when one end of the adjustment capacitor Cs is connected to the input path 120 while the switch SWs3 is off.

The analog voltage Vin is input to the input path 120 during the sampling. In the present embodiment, the voltage corresponding to the adjustment voltage is supplied to the input path 120 before the analog signal Vin is input to the input path 120. This can suppress the change in the voltage at the one ends of the capacitors C0 to C3 when the switches SW0 to SW3 and SWs3 are switched during the sampling. As a result, the generation of the kick-back noise during the sampling can be suppressed.

Although the adjustment capacitor Cs is not particularly limited to any kind, the adjustment capacitor Cs may have, for example, a capacitance value equal to or greater than combined capacitance of the plurality of capacitors C0 to C3. When the adjustment capacitor Cs has a capacitance value equal to or greater than the combined capacitance, the change in the voltage at the one ends of the capacitors C0 to C3 can be more surely suppressed during the sampling, and the generation of the kick-back noise can be suppressed.

The switch SWs1 connects the one end of the adjustment capacitor Cs to the input path 120 or the standard path 122. The switch SWs2 is arranged between another end of the adjustment capacitor Cs and the output path 124. The other end of the adjustment capacitor Cs is connected to the output path 124 when the switch SWs2 is on, and the other end of the adjustment capacitor Cs is cut off from the output path 124 when the switch SWs2 is off.

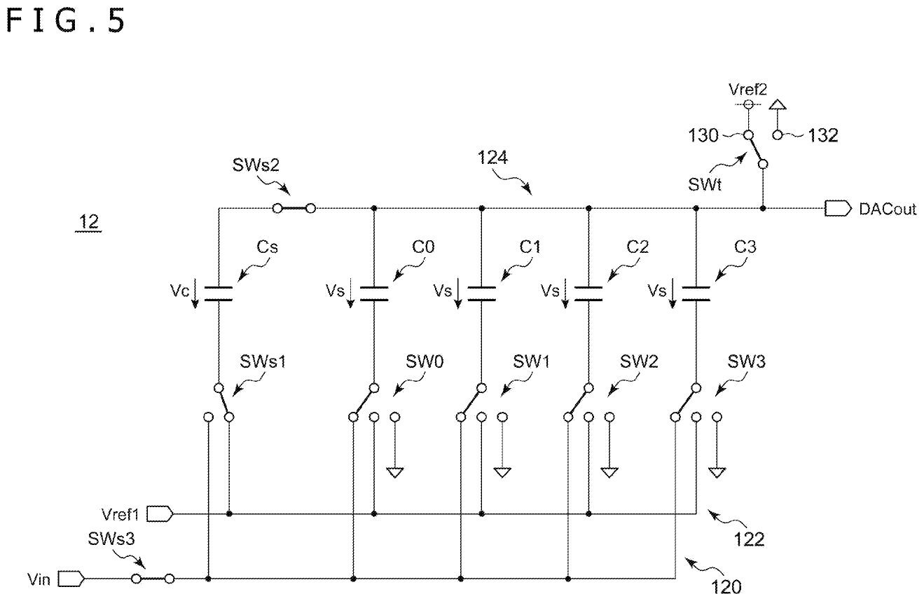

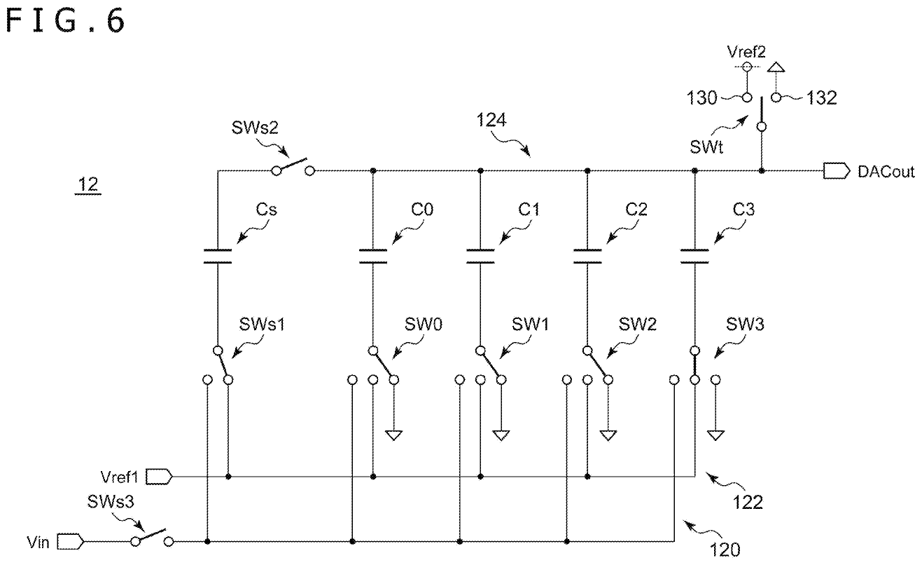

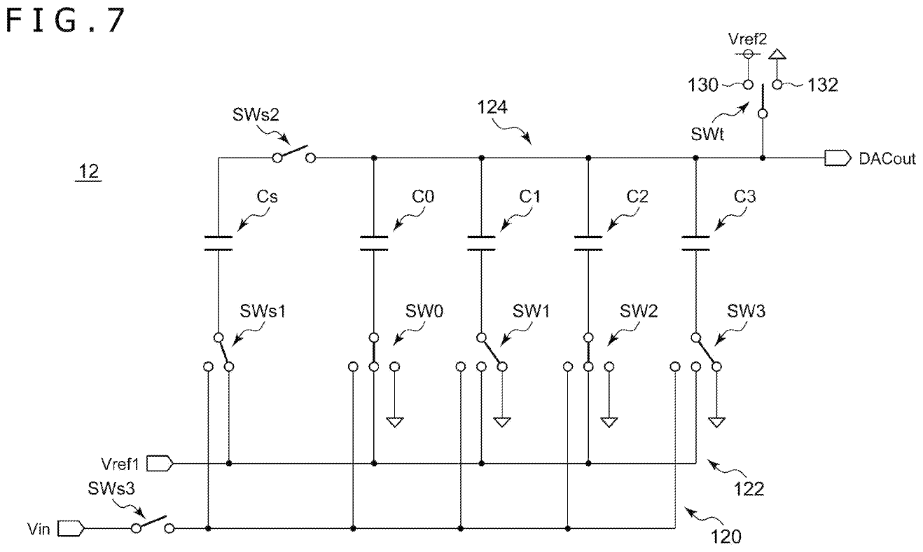

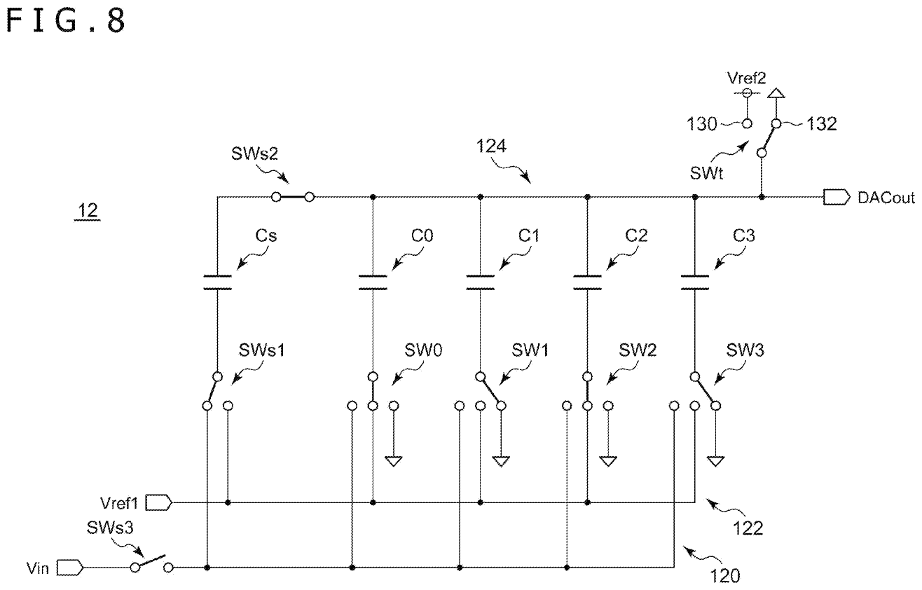

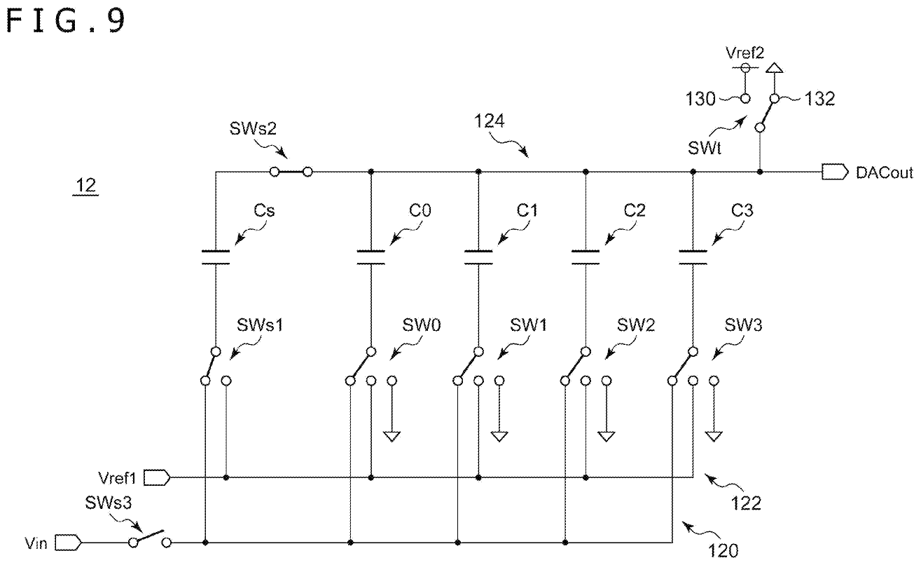

An example of an action of the capacitive DAC 12 according to the present embodiment will be described with reference to FIGS. 5 to 9. FIG. 5 depicts the capacitive DAC 12 during the sampling. FIG. 6 depicts the capacitive DAC 12 at the start of the successive approximation. FIG. 7 depicts the capacitive DAC 12 at the end of the successive approximation. FIG. 8 depicts the capacitive DAC 12 in adjusting the voltage of the input path 120. FIG. 9 depicts the capacitive DAC 12 in connecting the one ends of the plurality of capacitors C0 to C3 to the input path 120.

The sampling of the analog voltage Vin and the charging of the adjustment capacitor Cs in the capacitive DAC 12 will first be described with reference to FIG. 5. The capacitive DAC 12 according to the present embodiment supplies the analog voltage Vin to the plurality of capacitors C0 to C3 through the input path 120 to sample the analog voltage Vin.

Specifically, the switches SW0 to SW3 connect the one ends of the plurality of capacitors C0 to C3 to the input path 120 as illustrated in FIG. 5. The switch SWs3 is on, and the analog voltage Vin is input to the input path 120. The switch SWt connects the output path 124 to the comparison standard terminal 130, and the comparison standard voltage Vref2 is supplied to the output path 124. As a result, each of the plurality of capacitors C0 to C3 stores the charge corresponding to the analog voltage Vin and the comparison standard voltage Vref2, and the analog voltage Vin is sampled. In this case, a voltage of Vs (=Vin−½×Vref1) is applied to the one end of each of the plurality of capacitors C0 to C3 with respect to the other end of each of the capacitors C0 to C3. The plurality of capacitors C0 to C3 store the charge corresponding to the voltage Vs.

In the present embodiment, the adjustment capacitor Cs is charged with an adjustment voltage Vc during the sampling of the analog signal Vin. Specifically, the switch SWs1 connects the one end of the adjustment capacitor Cs to the standard path 122 as illustrated in FIG. 5. In this way, the reference voltage Vref1 is supplied to the one end of the adjustment capacitor Cs. The switch SWs2 is on, and the other end of the adjustment capacitor Cs is connected to the output path 124. In this way, the other end of the adjustment capacitor Cs is connected to the other end of each of the plurality of capacitors C0 to C3 through the output path 124, and the comparison standard voltage Vref2 is supplied to the other end of the adjustment capacitor Cs. As a result, the adjustment capacitor Cs is charged with the adjustment voltage Vc corresponding to the comparison standard voltage Vref2 and the reference voltage Vref1. Specifically, the adjustment capacitor Cs is charged with the adjustment voltage Vc=½×Vref1 (=Vref1−Vref2) with respect to the other end.

After a sampling time determined by the circuit configuration, for example, the switches SWs2 and SWt are turned off, and the charge stored in each of the plurality of capacitors C0 to C3 is held. The switch SWs3 is then turned off to complete the sampling of the analog voltage Vin.

The capacitive D/A converter 12 supplies the GND or the reference voltage Vref1 to the one end of each of the plurality of capacitors C0 to C3 to generate the analog output voltage DACout according to the digital input Din. Specifically, the switches SW0 to SW3 operate according to the digital input Din. More specifically, the switches SW0 to SW3 connect the one ends of the capacitors C0 to C2 to the respective ground terminals and connect the one end of the capacitor C3 to the standard path 122 as illustrated in FIG. 6. In this way, the output voltage DACout corresponding to the digital input Din is generated. The output voltage DACout is expressed by the following equation (1).

$$\begin{matrix}[ Math . 1 ] & \\ DAC out = \frac{1 C \cdot bit 0 + 2 C \cdot bit 1 + 4 C \cdot bit 2 + 8 C \cdot bit 3}{1 C + 2 C + 4 C + 8 C} \cdot V ref 1 - ( Vin - \frac{V ref 1}{2} ) & ( 1 )\end{matrix}$$

In equation (1), bit (n) (n represents integers 0 to 3) is a value (0 or 1) corresponding to the voltage supplied to the one end of the corresponding capacitor. In equation (1), bit0 corresponds to the capacitor C0, bit1 corresponds to the capacitor C1, bit2 corresponds to the capacitor C2, and bit3 corresponds to the capacitor C3. When the GND is supplied to the one end of the corresponding capacitor, bit (n) is 0. When the reference voltage Vref1 is supplied to the one end of the corresponding capacitor, bit (n) is 1.

The comparator 14 compares the output voltage DACout and the comparison standard voltage Vref2. The logic circuit 16 evaluates the bit3 (most significant bit), in reference to the comparison result obtained by the comparator 14. Specifically, the logic circuit 16 may determine that the bit3 is 1 when the output voltage DACout is smaller than the comparison standard voltage Vref2 and determine that the bit3 is 0 when the output voltage DACout is equal to or greater than the comparison standard voltage Vref2. The logic circuit 16 inputs the digital input Din to the capacitive DAC 12 according to the comparison result obtained by the comparator 14.

The operation of the switches SW0 to SW3 corresponding to the digital input Din in the capacitive DAC 12 and the comparison of the output voltage DACout and the comparison standard voltage Vref2 in the comparator 14 are repeated. The logic circuit 16 evaluates the remaining bits (bit0 to bit2) in reference to the result of the successive approximation by the comparator 14 and generates the digital output signal Dout.

FIG. 7 illustrates the capacitive DAC 20 after the generation of the digital output signal Dout by the logic circuit 16 following the successive approximation by the comparator 14. In this case, the switches SW0 to SW3 in the example connect the one ends of the capacitors C0 and C2 to the standard path 122 and connect the one ends of the capacitors C1 and C3 to the respective ground terminals. Hence, the digital output signal Dout indicates (0101).

The adjustment capacitor Cs supplies the voltage corresponding to the adjustment voltage Vc to the input path 120 before the next sampling is performed after the successive approximation by the comparator 14. In the present embodiment, the switch SWs2 is switched from off to on, and the output path 124 is connected to the other end of the adjustment capacitor Cs as illustrated in FIG. 8. In this case, the switch SWt connects the output path 124 to the ground terminal, and the GND is supplied to the other end of the adjustment capacitor Cs through the output path 124. The switch SWs1 connects the one end of the adjustment capacitor Cs to the input path 120 while the switch SWs3 is off. The adjustment capacitor Cs is charged in advance with the adjustment voltage Vc (=½×Vref1), and a voltage of ½×Vref1 is supplied to the input path 120.

As illustrated in FIG. 9, the switches SW0 to SW3 connect the one ends of the plurality of capacitors C0 to C3 to the input path 120. In this case, the voltage at the one end of each of the plurality of capacitors C0 to C3 changes from Vref1 to ½×Vref1 or from GND to ½×Vref1, and the amount of change is +½×Vref1.

If the one end of each of the plurality of capacitors C0 to C3 is connected to the input path 120 without the adjustment capacitor Cs being used to adjust the voltage of the input path 120, the voltage at the one end of each of the plurality of capacitors C0 to C3 changes from the Vref1 to the analog voltage Vin or from the GND to the analog voltage Vin. The analog voltage Vin usually indicates a value ranging from the GND to the Vref1. Thus, if the adjustment capacitor Cs is not used to adjust the voltage of the input path 120, the amount of change in the voltage at the one end of each of the plurality of capacitors C0 to C3 is Vref1 at most when the one end is connected to the input path 120. Hence, kick-back noise corresponding to the amount of variation Vref1 is generated at most. In contrast, the amount of change in the voltage can be suppressed to ±½×Vref1 in the present embodiment, and the generation of the kick-back noise based on the variation in the voltage can be suppressed.

In the next sampling in the capacitive DAC 12, the switch SWs1 connects the one end of the adjustment capacitor Cs to the standard path 122, and the switch SWs3 is switched from off to on. As a result, the analog voltage Vin is supplied to the input path 120. In this case, the voltage of the input path 120 is ½×Vref1 just before the switch SWs3 is turned on. Thus, the amount of variation of the voltage in the input path 120 caused by the switch of the switch SWs3 is ½×Vref1 at most. The change in the voltage is Vref1 at most if the adjustment capacitor Cs is not used. In contrast, the amount of change can be suppressed to ½×Vref1 at most in the present embodiment. This can suppress the generation of the kick-back noise during the sampling.

The successive approximation ADC 1 according to the present embodiment can suppress the generation of the kick-back noise without using the RC filter including a large-capacity capacitor, unlike the related technique. The successive approximation ADC 1 of the present embodiment can reduce the necessity of using the buffer circuit 10 for suppressing the generation of the kick-back noise. Thus, a high slew rate is not required, and this can suppress the increase in the power consumption. In this way, the successive approximation ADC 1 according to the present embodiment can suppress the increase in the power consumption and suppress the generation of the kick-back noise during the sampling without restricting the band of the analog voltage Vin.

Note that, in the example described in the present embodiment, the standard path 122 is connected to the one end of the adjustment capacitor Cs, and the output path 124 is connected to the other end of the adjustment capacitor Cs, to charge the adjustment capacitor Cs with the adjustment voltage. The configuration is not limited to this, and a path different from the standard path 122 and the output path 124 may be used to charge the adjustment capacitor Cs with the adjustment voltage.

In the example described in the present embodiment, the adjustment capacitor Cs supplies the voltage corresponding to the adjustment voltage to the input path 120 after the successive approximation is performed by the comparator 14. The configuration is not limited to this, and the adjustment capacitor Cs may supply the voltage corresponding to the adjustment voltage to the input path 120 during the successive approximation. In this case, while the switch SWs3 is off, the input path 120 may be connected to the one end of the adjustment capacitor Cs, and a path different from the output path 124 may be used to supply the GND to the other end of the adjustment capacitor Cs, to thereby supply the voltage corresponding to the adjustment voltage to the input path 120, for example.

### (Comparative Technique)

A successive approximation ADC according to a comparative technique includes a buffer circuit, a capacitive DAC, a comparator, and a logic circuit. In the comparative technique, the configuration of the capacitive DAC is different from the configuration of the capacitive DAC 12 according to the embodiment. The buffer circuit, the capacitive DAC, and the logic circuit according to the comparative technique may have substantially the same functions as the buffer circuit 10, the comparator 14, and the logic circuit 16 according to the embodiment, respectively.

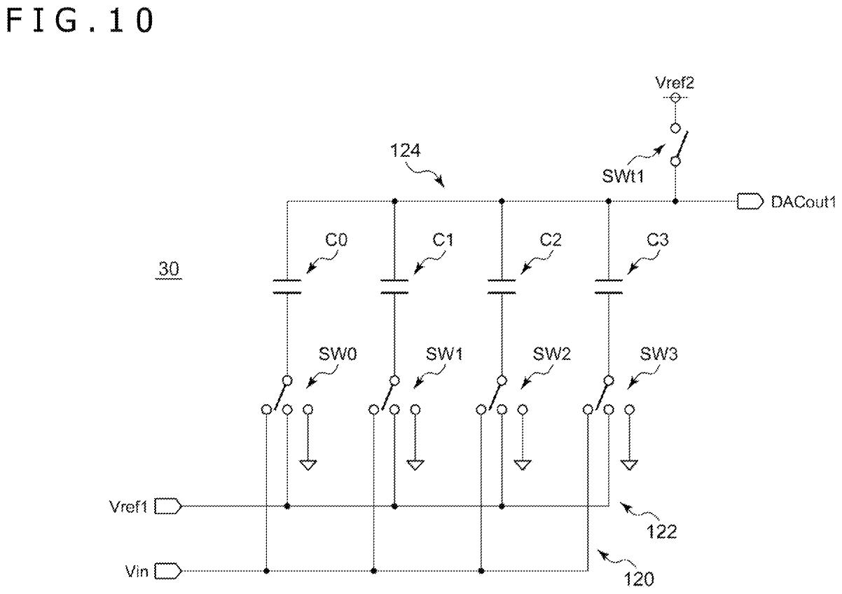

FIG. 10 is a circuit diagram of a capacitive DAC 30 according to the comparative technique. In FIG. 10, the same reference signs are provided to the components with substantially the same functions as the components of the capacitive DAC 12 according to the embodiment illustrated in FIG. 4, and the description will appropriately be omitted. The capacitive DAC 30 according to the comparative technique is mainly different from the capacitive DAC 12 according to the embodiment in that the capacitive DAC 30 does not include the adjustment capacitor Cs and the switch SWs3.

The capacitive DAC 30 according to the comparative technique includes the input path 120, the standard path 122, the output path 124, the plurality of capacitors C0 to C3, the switches SW0 to SW3, and a switch SWt1. While the switch SWt1 can supply the comparison standard voltage Vref2 to the output path 124, the switch SWt1 does not supply the GND to the output path 124, unlike the switch SWt according to the embodiment.

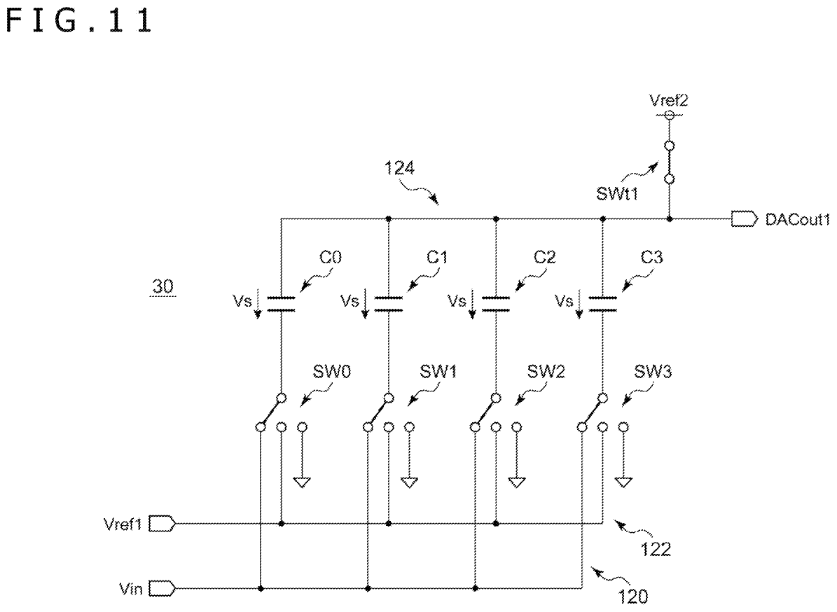

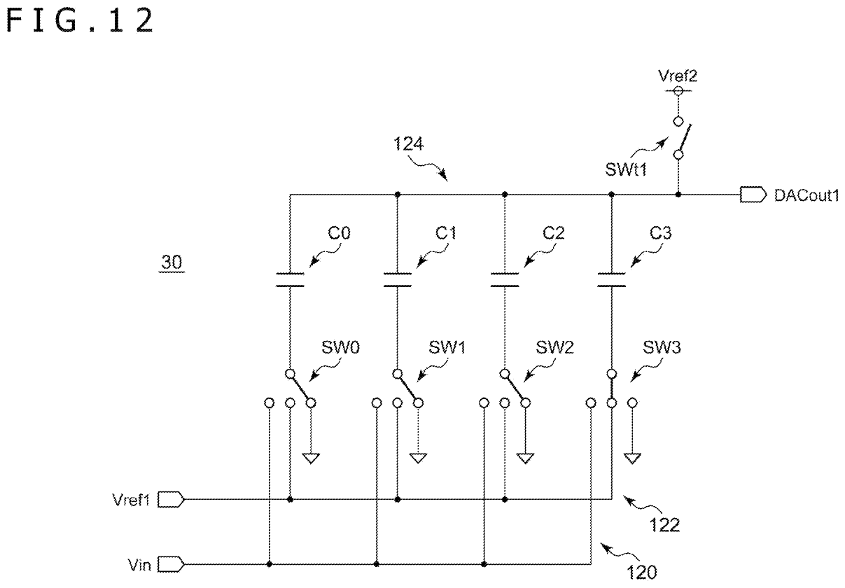

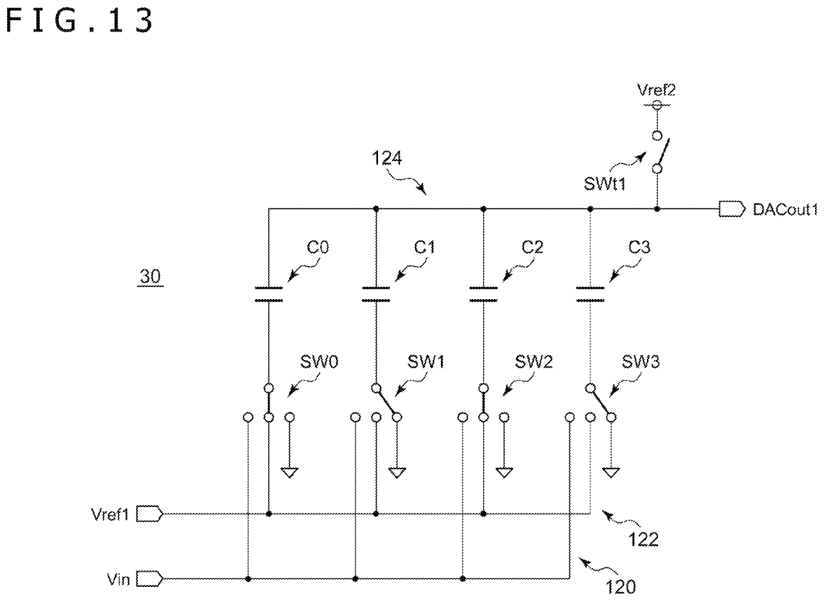

An action of the capacitive DAC 30 according to the comparative technique will be described with reference to FIGS. 11 to 13. FIG. 11 depicts the capacitive DAC 30 in sampling the analog voltage Vin. FIG. 12 depicts the capacitive DAC 30 at the start of the successive approximation. FIG. 13 depicts the capacitive DAC 30 at the end of the successive approximation.

During the sampling, the switches SW0 to SW3 connect the one ends of the plurality of capacitors C0 to C3 to the input path 120, respectively, as illustrated in FIG. 11. In this way, the analog voltage Vin is supplied to the one end of each of the plurality of capacitors C0 to C3. The switch SWt1 is on, and the comparison standard voltage Vref2 is supplied to the other end of each of the plurality of capacitors C0 to C3. In this way, each of the plurality of capacitors C0 to C3 is charged with the voltage Vs (=Vin−Vref2=Vin−½×Vref1), and the analog voltage Vin is sampled.

The switch SWt1 is then switched from on to off as illustrated in FIG. 12. The switches SW0 to SW3 connect the other ends of the capacitors C0 to C2 to the ground terminal and connect the other end of the capacitor C3 to the standard path 122, respectively. The comparator compares an output voltage DACout1 of the capacitive DAC 30 and the comparison standard voltage Vref2 and evaluates the most significant bit according to the result of comparison. The comparator then performs the successive approximation as in the embodiment, and the digital output signal corresponding to the analog input signal is generated.

When the successive approximation is finished, the one ends of the capacitors C0 and C2 are connected to the standard path 122, and the one ends of the capacitors C1 and C3 are connected to the ground terminal in the example as illustrated in FIG. 13. When the next sampling is performed, the switches SW0 to SW3 connect the other ends of the capacitors C0 to C3 to the input path 120. In this case, the analog voltage Vin is input to the input path 120. Thus, the voltage of the other end of each of the capacitors C0 and C2 changes from the Vref1 to the analog voltage Vin, and the voltage of the other end of each of the capacitors C1 and C3 changes from the GND to the analog voltage Vin. Thus, the amount of change in the voltage at the other end of each of the capacitors C0 to C3 is Vref1 at most, and the kick-back noise corresponding to the amount of change is generated.

In contrast, the capacitive DAC 12 according to the above embodiment can suppress the amount of change in the voltage at the other end of each of the capacitors C0 to C3 caused by the switch of the switches SW0 to SW3 to ½×Vref1 during the sampling. This can suppress the generation of the kick-back noise during the sampling.

### (Note)

Although specific terms are used to describe the embodiment of the present disclosure, the description is merely illustrated to help the understanding, and the description does not limit the present disclosure or the claims. The scope of the present disclosure is defined by the claims. The scope of the present disclosure includes not only the embodiment, but also embodiments, examples, and modifications not described here.

### (Supplement)

A mode of the technique disclosed in the present specification can be figured out as follows.

### (Item 1)

A successive approximation A/D converter that generates a digital output signal corresponding to an analog input signal, the successive approximation analog-to-digital converter including:
a capacitive digital-to-analog converter that samples an analog signal corresponding to the analog input signal and that generates an analog output signal corresponding to a sampling result and a digital input;
a comparator that compares the analog output signal and a comparison standard voltage; and
a control circuit that generates the digital input corresponding to a comparison result obtained by the comparator, in which
the capacitive digital-to-analog converter includes an input node that receives the analog signal, a plurality of capacitors, and an adjustment capacitor charged with an adjustment voltage, and supplies the analog signal to the plurality of capacitors through the input node to sample the analog signal,
the comparator performs successive approximation of the analog output signal in relation to each bit from a most significant bit to a least significant bit of the digital output signal and the comparison standard voltage,
the control circuit generates the digital output signal in reference to a result of the successive approximation by the comparator, and
the adjustment capacitor supplies a voltage corresponding to the adjustment voltage to the input node before next sampling is performed after the successive approximation.

### (Item 2)

The successive approximation analog-to-digital converter according to item 1, in which
the capacitive digital-to-analog converter further includes an output node connected to another end of each of the plurality of capacitors and configured to output the analog output signal, and
the adjustment capacitor supplies the voltage corresponding to the adjustment voltage to the input node when one end of the adjustment capacitor is connected to the input node and another end of the adjustment capacitor is connected to the output node supplied with a circuit standard voltage.

### (Item 3)

The successive approximation analog-to-digital converter according to item 2, further including:
a switch arranged between a circuit that outputs the analog signal and the input node, in which
the other end of each of the plurality of capacitors is connected to the input node when the switch is off and the one end of the adjustment capacitor is connected to the input node.

### (Item 4)

The successive approximation analog-to-digital converter according to item 1, in which
the capacitive digital-to-analog converter supplies a circuit standard voltage or a reference voltage to one end of each of the plurality of capacitors according to the digital input to thereby generate the analog output signal, and
the adjustment capacitor is charged with the adjustment voltage corresponding to the comparison standard voltage and the reference voltage when the reference voltage is supplied to one end of the adjustment capacitor and the comparison standard voltage is supplied to another end of the adjustment capacitor during the sampling of the analog signal.

### (Item 5)

The successive approximation analog-to-digital converter according to item 4, in which
the capacitive digital-to-analog converter further includes an output node connected to another end of each of the plurality of capacitors and configured to output the analog output signal, and
the other end of the adjustment capacitor is charged with the adjustment voltage when the other end of the adjustment capacitor is connected to the output node supplied with the comparison standard voltage during the sampling of the analog signal.

### (Item 6)

The successive approximation analog-to-digital converter according to any one of items 1 through 5, in which
the capacitive digital-to-analog converter supplies a circuit standard voltage or a reference voltage to one end of each of the plurality of capacitors according to the digital input to thereby generate the analog output signal, and
the adjustment voltage is a voltage one half of the reference voltage.

### (Item 7)

The successive approximation analog-to-digital converter according to any one of items 1 through 6, in which
capacitance of the adjustment capacitor is combined capacitance of the plurality of capacitors.

According to the present disclosure, a successive approximation A/D converter that can suppress the generation of the kick-back noise during the sampling can be provided.

What is claimed is:

1. A successive approximation analog-to-digital converter that generates a digital output signal corresponding to an analog input signal, the successive approximation analog-to-digital converter comprising:
a capacitive digital-to-analog converter that samples an analog signal corresponding to the analog input signal and that generates an analog output signal corresponding to a sampling result and a digital input;
a comparator that compares the analog output signal and a comparison standard voltage; and
a control circuit that generates the digital input corresponding to a comparison result obtained by the comparator, wherein
the capacitive digital-to-analog converter includes an input node that receives the analog signal, a plurality of capacitors, and an adjustment capacitor charged with an adjustment voltage, and supplies the analog signal to the plurality of capacitors through the input node to sample the analog signal,
the comparator performs successive approximation of the analog output signal in relation to each bit from a most significant bit to a least significant bit of the digital output signal and the comparison standard voltage,
the control circuit generates the digital output signal in reference to a result of the successive approximation by the comparator, and
the adjustment capacitor supplies a voltage corresponding to the adjustment voltage to the input node before next sampling is performed after the successive approximation.

2. The successive approximation analog-to-digital converter according to claim 1, wherein
the capacitive digital-to-analog converter further includes an output node connected to another end of each of the plurality of capacitors and configured to output the analog output signal, and
the adjustment capacitor supplies the voltage corresponding to the adjustment voltage to the input node when one end of the adjustment capacitor is connected to the input node and another end of the adjustment capacitor is connected to the output node supplied with a circuit standard voltage.

3. The successive approximation analog-to-digital converter according to claim 2, further comprising:
a switch arranged between a circuit that outputs the analog signal and the input node, wherein
the other end of each of the plurality of capacitors is connected to the input node when the switch is off and the one end of the adjustment capacitor is connected to the input node.

4. The successive approximation analog-to-digital converter according to claim 1, wherein
the capacitive digital-to-analog converter supplies a circuit standard voltage or a reference voltage to one end of each of the plurality of capacitors according to the digital input to thereby generate the analog output signal, and
the adjustment capacitor is charged with the adjustment voltage corresponding to the comparison standard voltage and the reference voltage when the reference voltage is supplied to one end of the adjustment capacitor and the comparison standard voltage is supplied to another end of the adjustment capacitor during the sampling of the analog signal.

5. The successive approximation analog-to-digital converter according to claim 4, wherein
the capacitive digital-to-analog converter further includes an output node connected to another end of each of the plurality of capacitors and configured to output the analog output signal, and
the other end of the adjustment capacitor is charged with the adjustment voltage when the other end of the adjustment capacitor is connected to the output node supplied with the comparison standard voltage during the sampling of the analog signal.

6. The successive approximation analog-to-digital converter according to claim 1, wherein
the capacitive digital-to-analog converter supplies a circuit standard voltage or a reference voltage to one end of each of the plurality of capacitors according to the digital input to thereby generate the analog output signal, and
the adjustment voltage is a voltage one half of the reference voltage.

7. The successive approximation analog-to-digital converter according to claim 1, wherein
capacitance of the adjustment capacitor is combined capacitance of the plurality of capacitors.
